(19) United States
(12) Patent Application Publication
(10) Pub. No.: US 2012/0261686 A1
(43) Pub. Date: Oct. 18, 2012

(54) LIGHT-EMITTING ELEMENT AND THE MANUFACTURING METHOD THEREOF

(76) Inventor: Chi Wei LU, Hsinchu (TW)

(21) Appl. No.: 13/085,160

(22) Filed: Apr. 12, 2011

(51) Int. Cl. H01L 33/38

(52) U.S. Cl. 257/91; 438/28; 257/E33.065

(57) ABSTRACT

A light-emitting element includes: a carrier; an adhesive layer formed on the carrier; and a plurality of light-emitting units disposed separately on the conductive adhesive layer, wherein each of the light-emitting units includes a first semiconductor layer, a light-emitting layer surrounding the first semiconductor layer, a second semiconductor layer surrounding the light-emitting layer; and a conductive structure connecting the first semiconductor layers of the light-emitting units to each other.

### TECHNICAL FIELD

The application relates to a light-emitting element and the manufacturing method thereof.

### DESCRIPTION OF BACKGROUND ART

The features of the light emitting diode (LED) mainly include a small size, high efficiency, long life, quick reaction, high reliability, and fine color. So far, the LED has been applied to electronic devices, vehicles, signboards, traffic signs, and many other applications. Along with the launch of the full-color LED, LED has gradually replaced traditional lighting apparatus such as fluorescent lights and incandescent lamps.

The key component of full-color LED is nitride-based light-emitting element emitting blue light or green light, and the main manufacturing method for forming nitride-based light-emitting element is that firstly providing a substrate such as sapphire or SiC, and growing a nitride-based light-emitting stack on the substrate.

### SUMMARY OF THE DISCLOSURE

A light-emitting element including: a carrier; an adhesive layer formed on the carrier; and a plurality of light-emitting units disposed separately on the adhesive layer, wherein each of the light-emitting units includes a first semiconductor layer, a light-emitting layer surrounding the first semiconductor layer, and a second semiconductor layer surrounding the light-emitting layer; and a conductive structure connecting the first semiconductor layers of the light-emitting units to each other.

A manufacturing method of a light-emitting element including steps of: providing an epitaxial structure; forming an insulating layer on the epitaxial structure, wherein the insulating layer has a plurality of holes; forming a plurality of light-emitting units, wherein a portion of each of the plurality of light-emitting units is formed from the epitaxial structure and protruding from each of the holes; and attaching a carrier to the plurality of light-emitting units.

A manufacturing method of a light-emitting element including steps of: providing a epitaxial substrate; forming a base layer on the epitaxial substrate; forming an insulating layer on the base layer, wherein the insulating layer has a plurality of holes; forming a plurality of light-emitting units, wherein a portion of each of the plurality of light-emitting units is formed from the base layer; attaching a carrier to the plurality of light-emitting units; and removing the epitaxial substrate.

### BRIEF DESCRIPTION OF THE DRAWINGS

FIG. 1A is a cross-sectional view of a light-emitting element of a first embodiment of the present application.

FIG. 1B is a top view of a light-emitting element of a first embodiment of the present application.

FIGS. 1C to 1K show a manufacturing method of a light-emitting element of a first embodiment of the present application.

FIG. 2 is a cross-sectional view of a light-emitting element of a second embodiment of the present application.

### DETAILED DESCRIPTION OF PREFERRED EMBODIMENTS

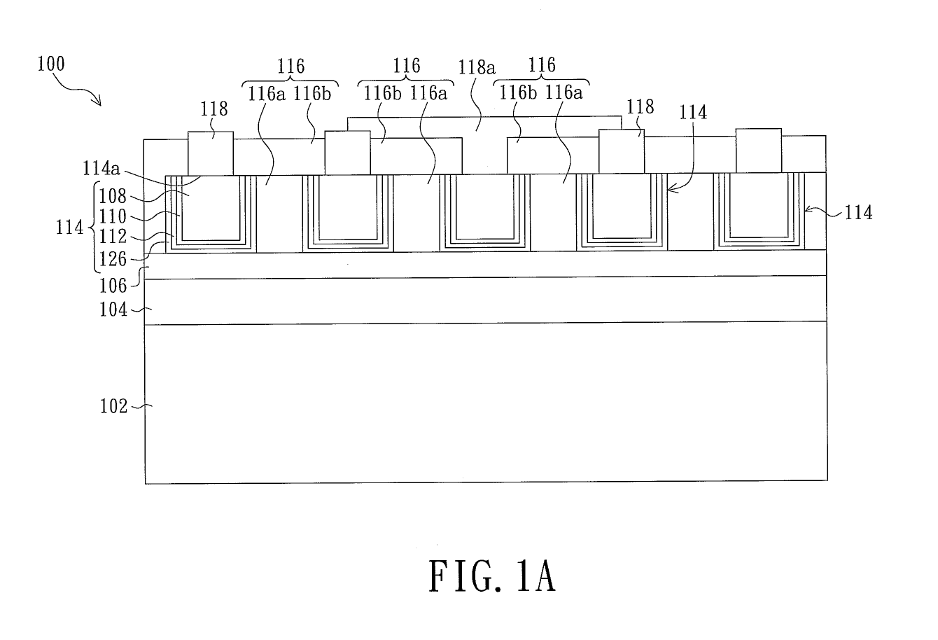

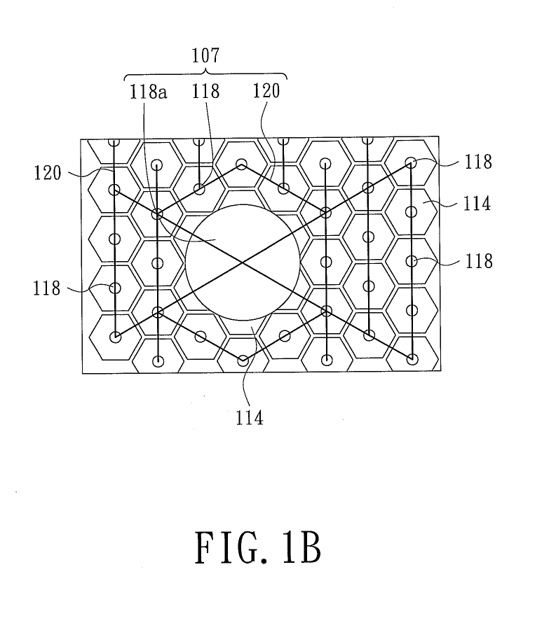

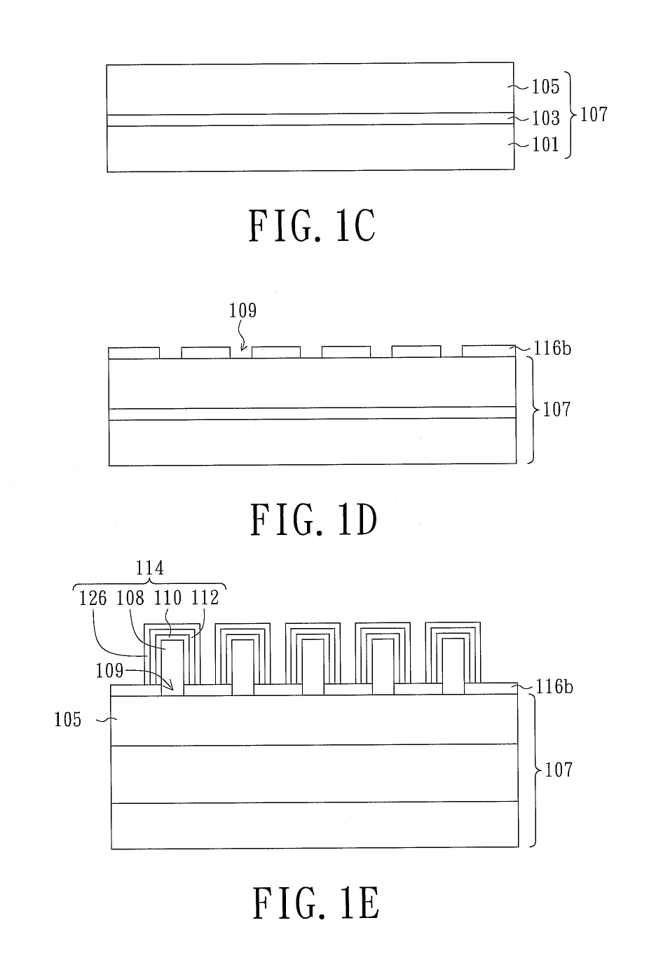

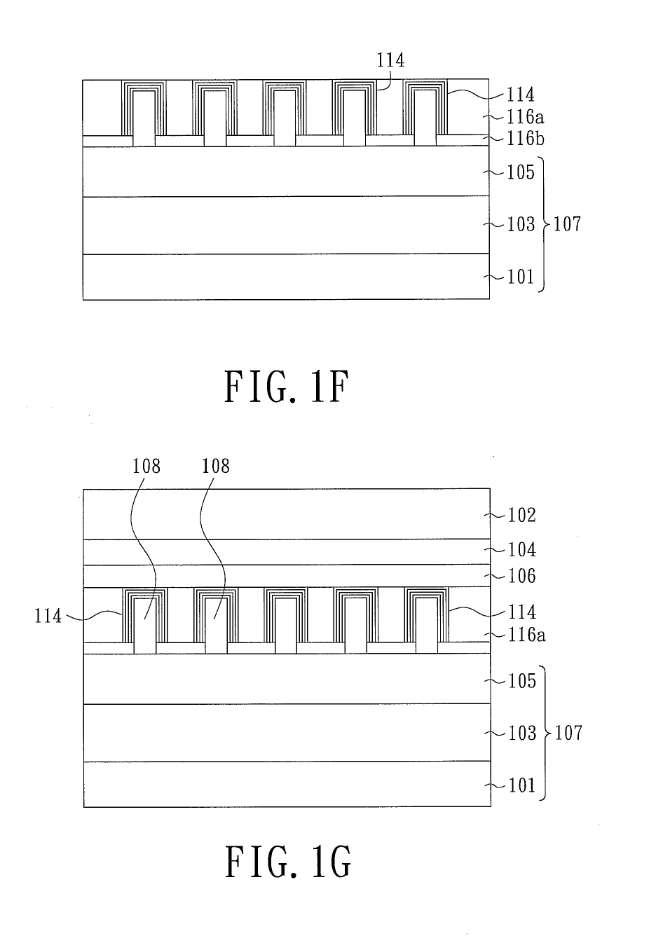

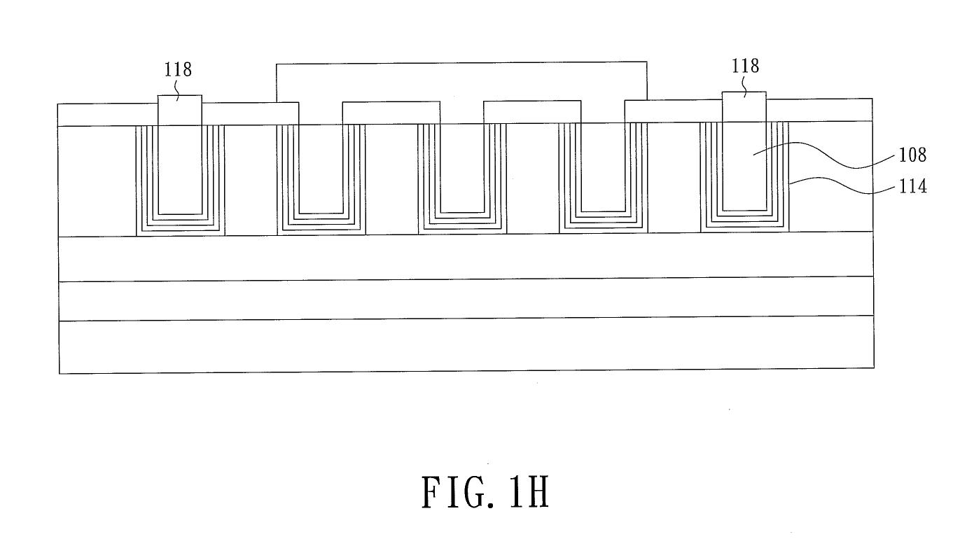

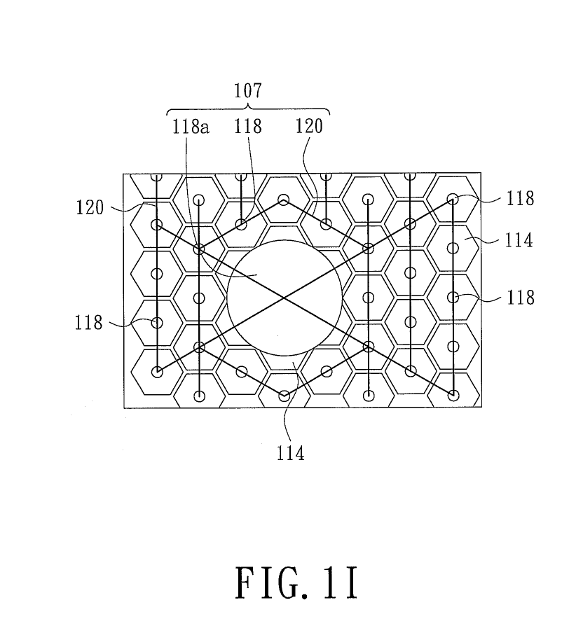

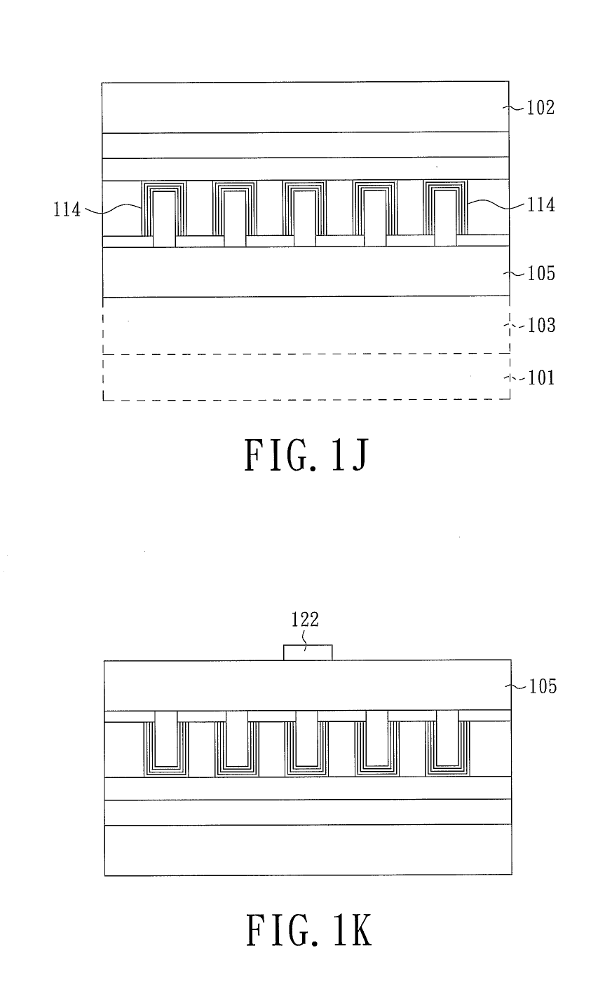

As shown in FIG. 1A and FIG. 1B, a light-emitting element 100 of a first embodiment of the present application includes: a carrier 102; an adhesive layer 104 formed on the carrier 102; a plurality of light-emitting units 114 disposed separately on the adhesive layer 104, wherein each of the light-emitting units 114 includes a first semiconductor layer 108, a light-emitting layer 110 formed on the bottom of the first semiconductor layer 108 and laterally surrounding the first semiconductor layer 108, a second semiconductor layer 112 formed on the bottom of the light-emitting layer 110 and laterally surrounding the light-emitting layer 110, and a conductive layer 126 including metal oxide or metal formed on the bottom of the second semiconductor layer 112 and laterally surrounding the second semiconductor layer 112; an insulating layer 116 has a first region 116a formed between the plurality of light-emitting units 114, and a second region 116b formed on the first region 116a and covering a partial region of the second semiconductor layer 112, the light-emitting layer 110, and the conductive layer 126; and a plurality of conductive contacts 118 formed on the first semiconductor layer 108. The material of the light-emitting units 114 can be nitride-based semiconductor, and each of the light-emitting units 114 can formed as a hexagonal column structure. The upper surface and the bottom surface of each of the light-emitting units 114 of hexagonal column are c-plane and −c-plane respectively, and the six side surfaces of each of the light-emitting units 114 are m-planes, wherein the total area of the m-planes are larger than that of the c-plane and −c-plane. The material of the adhesive layer 104 can be metal or metal alloy such as In, Sn, Ag, Au, Pt, Zn, Al, Ti, Pb, Pd, Ge, Cu, Ni, AuSn, InAg, InAu, AuBe, AuGe, AuZn, PbSn or PdIn. A reflecting layer 106 can be formed between the light-emitting units 114 and the adhesive layer 104, and the material thereof can be one or more than one material selected from a group consisting of Cu, Al, In, Sn, Au, Pt, Zn, Ag, Ti, Pb, Pd, Ge, N, Cr, Cd, Co, Mn, Sb, Bi, Ga, Tl, Se, Te, Po, Ir, Re, Rh, Os, W, Li, Na, K, Be, Mg, Ca, Sr, Ba, Zr, Mo, La, Cu—Sn, Cu—Zn, Cu—Cd, Sn—Pb—Sb, Sn—Pb—Z, Ni—Sn, Ni—Co, and Au alloy. The material of the conductive contact 118 can be Au or Au alloy. The carrier 102 can be a conductive substrate including semiconductor material such as Si, SiC or GaN, metal, ceramic, or other conductive materials. Referring to FIG. 1B, a conductive structure 107 including a plurality of conductive contacts 118, and a plurality of conductive lines 120 located between the plurality of conductive contacts 118 for connecting the first semiconductor layers 108 of the light-emitting units 114 to each other. The area of each of the light-emitting units 114 is preferably no less than 25 square microns for the disposition of the conductive contacts 118. A conductive contact 118a is formed on at least more than one light-emitting unit 114 and has an area large enough for connecting to an external power supply by wire bonding. The plurality of light-emitting units 114 are arranged as close as possible. To be more specific, any three of the plurality of light-emitting units 114 closest to each other can be arranged as an equilateral triangle. In one embodiment, the light-emitting units 114 are formed as a hexagonal column structure, the light-emitting units 114 can be arranged to form a pattern such as hexagon, rectangular or other shapes. In addition, the conductive contact 118a can cover more than one light-emitting unit 114 located at the center region of the pattern to directly connect to as many as light-emitting units 114.

As shown in FIG. 1C to FIG. 1K, a manufacturing method of the light-emitting element of the first embodiment of the present application is disclosed. Referring to FIG. 1C, an epitaxial structure 107 is formed by providing an epitaxial substrate 101, forming a buffer layer 103 on the epitaxial substrate 101 by epitaxial growth or deposition, and forming an base layer 105 on the buffer layer 103. The epitaxial substrate 101 can be sapphire, Si or SiC. The buffer layer 103 can be MN or GaN. The base layer 105 can be nitride-based semiconductor layer such as GaN, InGaN, or AlGaN. Referring to FIG. 1D, forming an insulating layer 116b having a plurality of holes 109 on the epitaxial structure 107. Referring to FIG. 1E, a plurality of light-emitting units 114 are formed, and the process for forming the light-emitting units 114 includes: forming a plurality of first semiconductor layers 108 from the epitaxial structure 107 and protruded from the holes 109 by epitaxial growth, conformably forming a plurality of light-emitting layers 110 on each of the first semiconductor layers 108 by epitaxial growth, conformably forming a plurality of second semiconductor layers 112 on each of the light-emitting layers 110 by epitaxial growth, and conformably forming a plurality of conductive layers 126 on each of the second semiconductor layers 112 by sputtering or evaporation. Each of the first semiconductor layers 108 is grown from the base layer 105 of the epitaxial structure 107, moreover, the material and the polarity thereof can be the same with that of the base layer 105. The second semiconductor layers 112 can be GaN series material such as GaN, InGaN, or AlGaN, and the polarity thereof is different from that of the first semiconductor layers 108. Referring to FIG. 1F, forming an insulating filler 116a on the insulating layer 116b and between the plurality of light-emitting units 114. The insulating filler 116a can be the same material with the insulating layer 116b, and the material of the insulating filler 116a and the insulating layer 116b can be SiNₓ or SiO₂ formed by deposition, or the material thereof can be such as silicone resin, BCB, epoxy, polyimide or PFCB formed by coating. Referring to FIG. 1G, a carrier 102 is attached to the light-emitting units. A reflecting layer 106 can be formed on the surface including the light-emitting units 114 and the insulating filler 116a, and an adhesive layer 104 can be formed between the reflecting layer 106 and the carrier 102 to attach the carrier 102 to the light-emitting units 114. The adhesive layer 104 can be formed by forming metal-attaching layers (not shown) on the carrier 102 side and the light-emitting units 114 side respectively, and the two metal-attaching layers are combined as the adhesive layer 104 by heating. After attaching the carrier 102 to the light-emitting units 114, the epitaxial substrate 101, buffer layer 103, and the base layer 105 can be sequentially removed, and after removing the epitaxial structure 107 entirely, the first semiconductor layers 108 of each of the light-emitting units 114 are exposed. Referring to FIG. 1H, a plurality of conductive contacts 118 are formed on each of the light-emitting units 114 and contacting the first semiconductor layer 108 thereof. Referring to FIG. 1I, forming a plurality of conductive lines 120 connected between the conductive contacts 118 and 118a. Referring to FIG. 1J, after attaching the carrier 102 to the light-emitting units 114 in FIG. 1G, the epitaxial substrate 101 and the buffer layer 103 are removed, and the base layer 105 remains. Referring to FIG. 1K, a metal contact 122 is formed on the base layer 105.

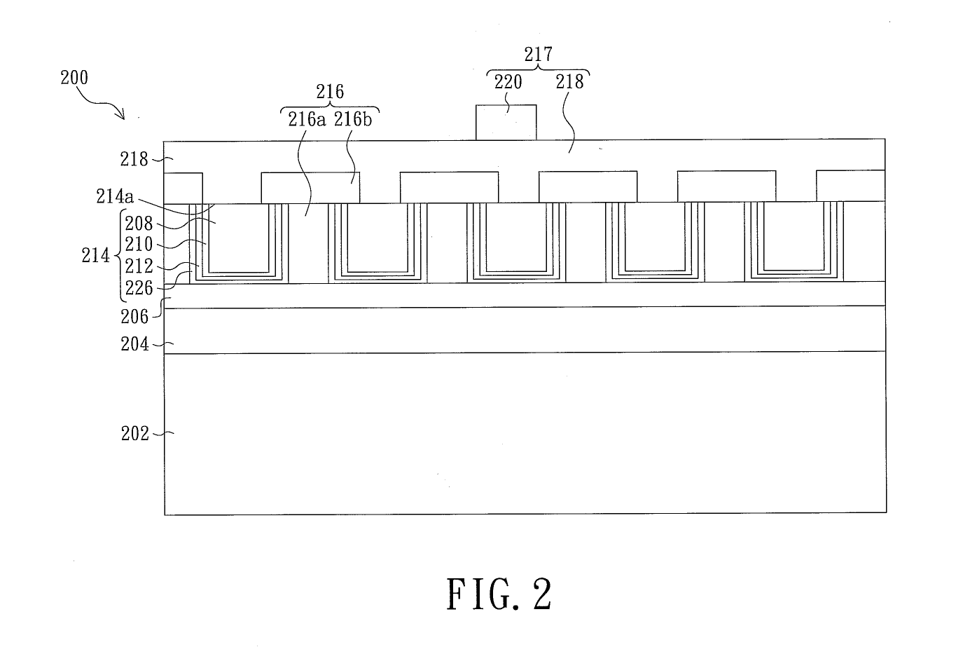

Referring to FIG. 2, a light-emitting element 200 of a second embodiment of the present application includes: a carrier 202; an adhesive layer 204 formed on the carrier 202; a plurality of light-emitting units 214 disposed separately on the adhesive layer 204, wherein each of the light-emitting units 214 includes a first semiconductor layer 208, a light-emitting layer 210 formed on the bottom of the first semiconductor layer 208 and laterally surrounding the first semiconductor layer 208, a second semiconductor layer 212 formed on the bottom of the light-emitting layer 210 and laterally surrounding the light-emitting layer 210, and a conductive layer 226 including metal oxide or metal formed on the bottom of the second semiconductor layer 212 and laterally surrounding the second semiconductor layer 212,; an insulating layer 216 has a first region 216a formed between the plurality of light-emitting units 214, and a second region 216b formed on the first region 216a and covering a partial region of the second semiconductor layer 212, the light-emitting layer 210, and the conductive layer 226; and a conductive structure 217 including a conductive film 218 formed on the plurality of light-emitting units 214 and contacting each of the plurality of the first semiconductor layers 208 thereof, and a metal contact 220 formed on the conductive film 218. The material of the adhesive layer 204 can be metal or metal alloy such as In, Sn, Au, Pt, Zn, Ti, Pb, Pd, Ge, Cu, Ni, AuSn, InAg, InAu, AuBe, AuGe, AuZn, PbSn or PdIn. A reflecting layer 206 can be formed between the light-emitting units 214 and the adhesive layer 204, and the material thereof can be one or more than one material selected from a group consisting of Cu, Al, In, Sn, Au, Pt, Zn, Ag, Ti, Pb, Pd, Ge, N, Cr, Cd, Co, Mn, Sb, Bi, Ga, Tl, Se, Te, Po, Ir, Re, Rh, Os, W, Li, Na, K, Be, Mg, Ca, Sr, Ba, Zr, Mo, La, Cu—Sn, Cu—Zn, Cu—Cd, Sn—Pb—Sb, Sn—Pb—Z, Ni—Sn, Ni—Co, and Au alloy. The material of the conductive film 218 can be metal oxide including ITO, InO, SnO, CTO, ATO, AZO, ZTO, ZnO. The conductive film 218 is formed on the light-emitting units 214 by sputtering or evaporation and contacts the first semiconductor layers 208, and then the metal contact 220 can be formed on the conductive film 218 by lithography and etching. The conductive film 218 can be also a nitride-based semiconductor layer, and the material and the polarity is the same with that of the first semiconductor layer 208.

Although the present application has been explained above, it is not the limitation of the range, the sequence in practice, the material in practice, or the method in practice. Any modification or decoration for present application is not detached from the spirit and the range of such.

What is claimed is:

1. A light-emitting element comprising:
a carrier;
an adhesive layer formed on the carrier;
a plurality of light-emitting units disposed separately on the adhesive layer, wherein each of the light-emitting units comprises a first semiconductor layer, a light-emitting layer surrounding the first semiconductor layer, and a second semiconductor layer surrounding the light-emitting layer; and
a conductive structure connecting the first semiconductor layers of more than one of the light-emitting units.

2. The light-emitting element of claim 1, wherein each of the light-emitting units further comprises a conductive layer surrounding the second semiconductor layer.

3. The light-emitting element of claim 1, further comprising an insulating layer comprising a first region formed between the light-emitting units, and a second region formed on the first region and covering a partial region of the light-emitting layer and the second semiconductor layer of each of the light-emitting units.

4. The light-emitting element of claim 1, wherein the conductive structure comprises a plurality of conductive contacts formed on each of the first semiconductor layers, and a plurality of conductive lines connecting the plurality of conductive contacts to each other.

5. The light-emitting element of claim 3, wherein the conductive structure comprises a conductive film covering the upper surface of the plurality of the light-emitting units and contacting the first semiconductor layers thereof.

6. The light-emitting element of claim 5, wherein the material of the conductive film comprises metal oxide, or the material of the conductive film is the same with that of the first semiconductor layer.

7. The light-emitting element of claim 5, wherein the conductive structure further comprises a metal contact formed on the conductive film.

8. The light-emitting element of claim 1, wherein the light-emitting layer is further formed on the bottom of the first semiconductor layer, and the second semiconductor layer is further formed on the bottom of the light-emitting layer.

9. The light-emitting element of claim 8, wherein each of the light-emitting units further comprises a conductive layer formed on the bottom of the second semiconductor layer.

10. The light-emitting element of claim 1, wherein any three of the plurality of light-emitting units closest to each others are arranged in an equilateral triangle.

11. A manufacturing method of a light-emitting element comprising steps of:
providing an epitaxial structure;
forming an insulating layer on the epitaxial structure, wherein the insulating layer has a plurality of holes;
forming a plurality of light-emitting units, wherein a portion of each of the plurality of light-emitting units is formed from the epitaxial structure and protruding from each of the holes; and
attaching a carrier to the plurality of light-emitting units.

12. The manufacturing method of a light-emitting element of claim 11, wherein the method of forming the plurality of light-emitting units comprises steps of: forming a plurality of first semiconductor layers from the epitaxial structure and protruding the plurality of holes; conformably forming a plurality of light-emitting layer on each of the first semiconductor layers; and conformably forming a second semiconductor layer on the light-emitting layers.

13. The manufacturing method of a light-emitting element of claim 12, wherein the process of forming the plurality of light-emitting units further comprises a step of conformably forming a conductive layer on the second semiconductor layer.

14. The manufacturing method of a light-emitting element of claim 12, wherein the step of providing the epitaxial structure comprises providing an epitaxial substrate, and forming a base layer on the epitaxial substrate.

15. The manufacturing method of a light-emitting element of claim 14, wherein the step of providing the epitaxial structure further comprises forming a buffer layer on the epitaxial substrate before forming the base layer.

16. The manufacturing method of a light-emitting element of claim 14, further comprising removing the epitaxial structure to expose the first semiconductor layer.

17. The manufacturing method of a light-emitting element of claim 16, further comprising forming a metal oxide layer covering the upper surface of the plurality of the light-emitting units and contacting the first semiconductor layers, and forming a metal contact on the metal oxide layer after removing the epitaxial structure, or forming a plurality of conductive contacts on each of the exposed first semiconductor layers of the plurality of light-emitting units, and forming a plurality of conductive lines connecting the plurality of conductive contacts to each other after removing the epitaxial structure.

18. The manufacturing method of a light-emitting element of claim 15, further comprising removing the epitaxial substrate and the buffer layer to expose the base layer after attaching the carrier to the light-emitting units, and forming a metal contact on the base layer.

19. The manufacturing method of a light-emitting element of claim 11, wherein the method of attaching the carrier to the plurality of light-emitting units comprises steps of forming metal-attaching layers on the upper surface of the light-emitting units and one side of the carrier respectively, and combining the two metal-attaching layers to form a adhesive layer.

20. A manufacturing method of a light-emitting element comprising steps of:
providing an epitaxial substrate;
forming a base layer on the epitaxial substrate;
forming an insulating layer on the base layer, wherein the insulating layer has a plurality of holes;
forming a plurality of light-emitting units, wherein a portion of each of the plurality of light-emitting units is formed from the base layer and protruding from each of the holes;
attaching a carrier to the plurality of light-emitting units; and
removing the epitaxial substrate.
